(19) United States
(12) Patent Application Publication
(10) Pub. No.: US 2015/0293443 A1
(43) Pub. Date: Oct. 15, 2015

(54) PHOTOSENSITIVE RESIN COMPOSITION, PHOTOSENSITIVE ELEMENT, METHOD FOR FORMING RESIST PATTERN, AND METHOD FOR MANUFACTURING PRINTED WIRING BOARD

(71) Applicant: HITACHI CHEMICAL COMPANY, LTD., Chiyoda-ku, Tokyo (JP)

(72) Inventors: Shota Okade, Hitachi-shi (JP); Masahiro Miyasaka, Hitachi-shi (JP); Yukiko Muramatsu, Hitachi-shi (JP)

(73) Assignee: Hitachi Chemical Company, Ltd., Chiyoda-ku, Tokyo (JP)

(21) Appl. No.: 14/443,440

(22) PCT Filed: Nov. 14, 2013
(86) PCT No.: PCT/JP2013/080831

§ 371 Date: May 18, 2015

(30) Foreign Application Priority Data
Nov. 20, 2012 (JP) 2012-254405

(51) Int. Cl. G03F 7/004; H05K 3/00; H05K 3/18; G03F 7/20; G03F 7/40

(52) U.S. Cl. CPC G03F 7/004; G03F 7/2002; G03F 7/40; H05K 3/184; H05K 3/188; H05K 3/0017

(57) ABSTRACT

The invention provides a photosensitive resin that includes: a binder polymer that has a structural unit derived from (meth)acrylic acid, a structural unit derived from styrene or α-methyl styrene, and a structural unit derived from benzyl (meth)acrylate; a photopolymerizable compound including a first bisphenol di(meth)acrylate that has an ethyleneoxy group and a propyleneoxy group, in which a number of structural units of the ethyleneoxy group is from 1 to 20 and a number of structural units of the propyleneoxy group is from 2 to 7, and in which a total number of structural units of the ethyleneoxy group and the propyleneoxy group is more than 10; and a photopolymerization initiator.

### TECHNICAL FIELD

The present invention relates to a photosensitive resin composition, a photosensitive element, a method for forming a resist pattern, and a method for manufacturing a printed wiring board.

### BACKGROUND ART

In the field of manufacturing printed wiring boards, photosensitive resin compositions have been widely employed as resist materials used for etching or plating. The photosensitive resin composition is often used as a photosensitive element (layered product) provided with a support film and a layer which is formed on the support film using the photosensitive resin composition (hereinafter, sometimes referred to as “photosensitive resin composition layer”).

For example, the printed wiring board is manufactured as follows. First, the photosensitive resin composition layer of the photosensitive element is formed (laminated) on a substrate for forming circuits (photosensitive layer forming process). The support film is then released and removed, and the predetermined area of the photosensitive resin composition layer is irradiated with active light rays to cure the exposed area (exposure process). The unexposed area of the photosensitive resin composition layer is then removed (developed) from the substrate, thereby forming a resist pattern consisting of the cured material of the photosensitive resin material (hereinafter, sometimes referred to as “resist cured product”) on the substrate (developing process). The resist pattern obtained is used as a mask for etching or plating to form a circuit on the substrate (circuit forming process), and finally the resist pattern is released and removed to manufacture a printed wiring board (releasing process).

As an exposure method, a method in which exposure is carried out through a photomask using a mercury lamp as a light source is conventionally employed. Recently, an exposure method called DLP (Digital Light Processing) or LDI (Laser Direct Imaging) has been proposed as a direct writing exposure method that allows direct formation of patterns based on digital data on the photosensitive resin composition layer. Such direct writing exposure method has improved alignment accuracy than the exposure method through a photomask and allows formation of finer patterns, and therefore increasingly used to manufacture substrates for high density package substrates.

In general, in the exposure process, the exposure time is required to be reduced in order to improve the production efficiency. In the above direct writing exposure method, however, monochromatic light such as laser is used as a light source and the substrate is irradiated with light rays while scanning. Therefore, the direct writing exposure method tends to require a longer exposure time compared to the conventional exposure method via a photomask. Accordingly, in order to reduce the exposure time to improve the production efficiency, it is necessary to improve the sensitivity of the photosensitive resin composition than the conventional one.

Meanwhile, in association with recent increase in density of printed wiring boards, the demand for a photosensitive resin composition that allows formation of a resist pattern with sufficient resolution (resolution property) and adhesiveness is increasing. In particular, a photosensitive resin composition that allows formation of a resist pattern having a L/S (line width/space width) of 10/10 (unit: μm) or less in manufacture of a package substrate is required.

In general, increase in resolution of the resist pattern is achieved by, for example, increasing the crosslink density after curing of the photosensitive resin composition. However, the resist pattern is hard and becomes fragile when the crosslink density in increased, and the problem of cracking of the resist pattern easily occurs in a conveyance process or the like. In order to solve this problem, the technique of increasing flexibility of the resist pattern is proposed. However, when the flexibility is increased, the resist pattern easily bends, which fact results in reduction in resolution property. Therefore, the features of increasing the resolution and flexibility are inconsistent with each other in the resulting resist pattern.

Moreover, in the developing process, it is necessary to shorten the time required for releasing the uncured photosensitive resin composition so as to improve the production efficiency.

In order to meet these demands, various photosensitive resin compositions have been examined in the past.

A photosensitive resin composition in which the above required features are improved by using a specific binder polymer, a photopolymerizable compound, a photopolymerization initiator, and a sensitizing dye is disclosed in, for example, Japanese Patent Application Laid-Open (JP-A) Nos. 2005-301101, 2007-114452, and 2007-122028, and International Publication Nos. WO 08/07848, WO 10/098175, WO 10/098183, and WO 12/067107.

### SUMMARY OF INVENTION

### Technical Problem

However, there is still room for improvement of the conventional photosensitive resin composition, in order to achieve excellent flexibility while maintaining resolution and adhesiveness of the resulting resist pattern and to further improve the resolution.

The object of the present invention is to provide a photosensitive resin composition that allows formation of a resist pattern satisfactory in terms of all of the properties of resolution, adhesiveness, and flexibility with excellent developability, a photosensitive element using the photosensitive resin composition, a method of forming a resist pattern, and a method of manufacturing a printed wiring board.

### Solution to Problem

As a result of intensive studies by the present inventors to solve the above problems, it was found that a photosensitive resin composition that allows formation of a resist pattern satisfactory in terms of all of the properties of resolution, adhesiveness, and flexibility with excellent developability can be obtained, by combining a photopolymerizable compound that includes an ethyleneoxy group having from 1 to 20 structural units and a propyleneoxy group having from 2 to 7 structural units, with the total number of the structural unit being more than 10, and that includes a bisphenol structure and two ethylenically unsaturated bonds with a binder polymer that has a structural unit derived from (meth)acrylic acid, a structural unit derived from styrene, and a structural unit derived from benzyl (meth)acrylate, and the present invention has been completed.

That is, according to the first aspect of the present invention, the photosensitive resin composition includes: a binder polymer that has a structural unit derived from (meth)acrylic acid, a structural unit derived from styrene or α-methyl styrene, and a structural unit derived from benzyl (meth)acrylate; a photopolymerizable compound comprising a first bisphenol di(meth)acrylate that has an ethyleneoxy group and a propyleneoxy group, in which a number of structural units of the ethyleneoxy group is from 1 to 20 and a number of structural units of the propyleneoxy group is from 2 to 7, and in which a total number of structural units of the ethyleneoxy group and the propyleneoxy group is more than 10; and a photopolymerization initiator.

According to the above aspect, the photosensitive resin composition allows formation of a resist pattern satisfactory in terms of all of the properties of resolution, adhesiveness, and flexibility with excellent developability. The photosensitive resin composition allows formation of a resist pattern having a L/S (line width/space width) of 10/10 (unit: μm) or less.

It is preferable that the photosensitive resin composition further includes at least one sensitizing dye selected from the group consisting of a pyrazoline derivative and a bis-alkoxy anthracene, in terms of further improving sensitivity, and resolution, adhesiveness, flexibility and release property after curing of the resulting resist pattern.

It is preferable that the photosensitive resin composition further includes, a second bisphenol di(meth)acrylate, which is different from the first bisphenol di(meth)acrylate, and which has an ethyleneoxy group, in which a number of the structural units of the ethyleneoxy group is 8 or less, in terms of further improving resolution, adhesiveness and flexibility, and developability.

According to the second aspect of the present invention, a photosensitive element includes: a support film; and a photosensitive resin layer that is provided on the support film and that is a coating film of the photosensitive resin composition according to the first embodiment. In a case in which the photosensitive element is used, the resist pattern specifically satisfactory in terms of all of the properties of resolution, adhesiveness, flexibility, and resist shape can be efficiently formed with excellent sensitivity and resolution.

According to the third aspect of the present invention, a method of forming a resist pattern includes: a process of forming, on a substrate, a photosensitive resin composition layer that is a coating film of the photosensitive resin composition according to the first aspect (photosensitive layer forming process); a process of irradiating at least a part of an area of the photosensitive resin composition layer with active light rays (exposure process); and a process of removing an area, other than the area of the photosensitive resin composition layer irradiated with active light rays, from the substrate (developing process). According to the method of forming a resist pattern, the resist pattern satisfactory in terms of all of the properties of resolution, adhesiveness, and flexibility can be efficiently obtained with excellent sensitivity and developability.

In the method of forming a resist pattern, the wavelength of the active light rays is preferably set to a range of from 340 nm to 430 nm. As a result, the resist pattern having remarkable resolution, adhesiveness, flexibility, and resist shape can be obtained more efficiently with excellent sensitivity and developability.

According to the fourth aspect of the present invention, a method of manufacturing a printed wiring board includes a process of etching or plating the substrate on which the resist pattern was formed by the method of forming a resist pattern. According to the manufacturing method, the printed wiring board with high density wiring such as a high density package substrate can be effectively manufactured with excellent accuracy and productivity.

### Advantageous Effects of Invention

According to the present invention, there can be provided a photosensitive resin composition that allows formation of a resist pattern satisfactory in terms of all of the properties of resolution, adhesiveness, and flexibility with excellent developability; a photosensitive element using the photosensitive resin composition; a method of forming a resist pattern; and a method of manufacturing a printed wiring board.

### BRIEF DESCRIPTION OF DRAWINGS

FIG. 1 is a schematic cross sectional view illustrating an embodiment of a photosensitive element according to the present invention.

FIGS. 2(a) to 2(f) are schematic perspective views illustrating an example of a manufacturing method of a printed wiring board by a semi-additive process.

### DESCRIPTION OF EMBODIMENTS

Hereinbelow, an embodiment to implement the present invention is described in detail. However, the present invention is not limited to the following embodiments. As used herein, the term “(meth)acrylic acid” means acrylic acid or methacrylic acid, the term “(meth)acrylate” means an acrylate or a corresponding methacrylate, and the term “(meth)acryloyloxy group” means an acryloyloxy group or a methacryloyloxy group. The term “(poly)ethyleneoxy” as used herein means at least one of an ethyleneoxy group or a polyethyleneoxy group in which two or more ethylene groups are linked via an ether bond. The ethyleneoxy group is a group represented by (—CH₂CH₂—O—), and also referred to as “oxyethylene group”. The term “(poly)propyleneoxy group” as used herein means at least one of propyleneoxy group or polypropyleneoxy group in which two or more propylene groups are linked via an ether bond. The propyleneoxy group is a group represented by (—CHCH₃CH₂—O—), a group represented by (—CH₂CHCH₃—O—), or a group represented by (—CH₂CH₂CH₂—O—), and also referred to as “oxypropylene group”. The term “EO-modified” compound means a compound having a (poly)ethyleneoxy group; “PO-modified” compound means a compound having a (poly)propyleneoxy group; and “EO, PO-modified” compound means a compound having both a (poly)ethyleneoxy group and a (poly)propyleneoxy group.

The term “process” as used herein indicates not only a separate process but also a process that is not clearly distinguished from other process as long as the desired effect of the process is obtained therefrom. In the present specification, each numerical range specified using “(from) . . . to . . . ” represents a range including the numerical values noted before and after “to” as the minimum value and the maximum value, respectively. Furthermore, when plural kinds of substances that correspond to the same component exist in the composition, the amount of the component in the composition refers to the total mass of the plural kinds of substances unless otherwise specified. The term “layer” as used herein indicates not only a structure having a shape formed on a whole surface but also a structure having a shape formed on a part of a surface when observed in a plane view. The term “layered” as used herein indicates “provided on or above”, in which two or more layers may be linked or detachable.

Photosensitive Resin Composition

A photosensitive resin composition according to an embodiment of the present invention includes component (A): a binder polymer that has a structural unit derived from (meth)acrylic acid, a structural unit derived from styrene or α-methyl styrene, and a structural unit derived from benzyl (meth)acrylate; component (B): a photopolymerizable compound including a first bisphenol di(meth)acrylate that has an ethyleneoxy group and a propyleneoxy group, in which a number of structural units of the ethyleneoxy group is from 1 to 20 and a number of structural units of the propyleneoxy group is from 2 to 7, and in which a total number of structural units of the ethyleneoxy group and the propyleneoxy group is more than 10; and component (C): a photopolymerization initiator. The photosensitive resin composition may further include other components if necessary.

In a case in which the first bisphenol di(meth)acrylate that has an ethyleneoxy group having from 1 to 20 structural units and a propyleneoxy group having from 2 to 7 structural units, with the total number of the structural unit of the ethyleneoxy group and the propyleneoxy group being more than 10, as the photopolymerizable compound and the binder polymer that has a structural unit derived from (meth)acrylic acid, a structural unit derived from styrene or α-methyl styrene, and a structural unit derived from benzyl (meth)acrylate are included, it is possible to configure the photosensitive resin composition that allows formation of a resist pattern satisfactory in terms of all of the properties of sensitivity, resolution, adhesiveness, and flexibility with excellent developability. The detailed reason for this effect is not thoroughly understood, but the inventors offer the following conjecture. That is, the use of the photopolymerizable compound including a propyleneoxy group and a structure derived from bisphenol A, which are hydrophobic and have an effect of lowering the degree of swelling, and an ethyleneoxy group having excellent flexibility, in combination with the binder polymer having a specific structure results in formation of a coarse cross-linked network with a low degree of swelling and improvement in the balance between the contradicting features of adhesiveness and developability. In addition, the use of the photopolymerizable compound in combination with a binder polymer that has a structural unit derived from styrene or α-methyl styrene and a structural unit derived from benzyl (meth)acrylate results in improvement in resolution and flexibility.

Component (A): Binder Polymer

The photosensitive resin composition includes, as component (A), at least one binder polymer that has a structural unit derived from (meth)acrylic acid represented by the following Formula (1), a structural unit derived from styrene or α-methyl styrene represented by the following Formula (2), and a structural unit derived from benzyl (meth)acrylate represented by the following Formula (3).

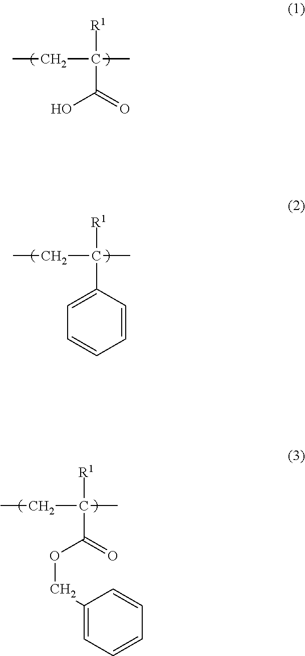

In Formulae (1), (2) and (3), each of R¹, R² and R³ independently represents a hydrogen atom or a methyl group, and preferably all of IV, R² and R³ represent a methyl group.

The binder polymer can be obtained, for example, by radical polymerization of (meth)acrylic acid, styrene or α-methyl styrene, and benzyl(meth)acrylate, as polymerizable monomers (monomers), and optionally other polymerizable monomer, using an ordinary method.

The other polymerizable monomer is not particularly limited as long as it is different form (meth)acrylic acid, styrene, and benzyl (meth)acrylate and polymerizable with (meth)acrylic acid, styrene or α-methyl styrene, and benzyl (meth)acrylate. Examples of the other polymerizable monomer include (meth)acrylates such as alkyl (meth)acrylate, cycloalkyl (meth)acrylate, a derivative of benzyl (meth)acrylate, furfuryl (meth)acrylate, tetrahydrofurfuryl (meth)acrylate, isobornyl (meth)acrylate, adamantyl (meth)acrylate, dicyclopentanyl (meth)acrylate, dimethylamonoethyl (meth)acrylate, diethylaminoethyl (meth)acrylate, glycidyl (meth)acrylate, 2,2,2-trifluoroethyl (meth)acrylate, 2,2,3,3-tetrafluoropropyl (meth)acrylate, dicyclopentenyloxyethyl (meth)acrylate, dicyclopentanyloxyethyl (meth)acrylate, isobonyloxyethyl (meth)acrylate, cyclohexyloxyethyl (meth)acrylate, adamantyloxyethyl (meth)acrylate, dicyclopentenyloxypropyloxyethyl (meth)acrylate, dicyclopentanyloxypropyloxyethyl (meth)acrylate, or adamantyloxypropyloxyethyl (meth)acrylate; derivatives of (meth)acrylic acid such as α-bromoacrylic acid, α-chloroacrylic acid, β-furyl (meth)acrylic acid, or β-styl(meth)acrylic acid; polymerizable styrene derivatives whose aromatic ring is substituted such as vinyltoluene; acrylamides such as diacetone acrylamide; acrylonitriles; ether compounds of vinyl alchols such as vinyl-n-butyl ether; maleic acid; maleic anhydride; maleic monoesters such as monomethyl maleate, menoethyl maleate, or monoisopropyl maleate; and derivatives of unsaturated carbonic acids such as fumaric acid, cinnamic acid, α-cyanocinnamic acid, itaconic acid, crotonic acid, or popiolic acid. These compounds may be used singly, or in any combination of two or more kinds thereof.

In the binder polymer, the content ratio of the structural unit derived from benzyl (meth)acrylate based on the total mass (100% by mass, the same applies hereafter) of the polymerizable monomer for constituting the binder polymer is preferably from 3% by mass to 85% by mass, more preferably from 5% by mass to 75% by mass, still more preferably from 10% by mass to 70% by mass, and even more preferably from 10% by mass to 50% by mass, in terms of excellent resolution and release property. In terms of excellent resolution, the content ratio is preferably 3% by mass or more, more preferably 5% by mass or more, and still more preferably 10% by mass or more. In terms of excellent release property and adhesiveness, the content ratio is preferably 85% by mass or less, more preferably 75% by mass or less, still more preferably 70% by mass or less, and even more preferably 50% by mass or less.

In the binder polymer, the content ratio of the structural unit derived from styrene or α-methyl styrene based on the total mass of the polymerizable monomer for constituting the binder polymer is preferably from 10% by mass to 70% by mass, more preferably from 15% by mass to 60% by mass, and still more preferably from 20% by mass to 55% by mass, in terms of excellent adhesiveness and release property of the resulting resist pattern. In terms of excellent adhesiveness of the resulting resist pattern, the content ratio is preferably 10% by mass or more, more preferably 15% by mass or more, and still more preferably 20% by mass or more. In terms of excellent release property of the resulting resist pattern, the content ratio is preferably 70% by mass or less, more preferably 60% by mass or less, and still more preferably 55% by mass or less.

It is preferable that the binder polymer further include a structural unit derived from an alkyl (meth)acrylate, from the viewpoint of improving developability and release property.

The alkyl(meth)acrylate is preferably an alkyl(meth)acrylate that has an alkyl group having from 1 to 12 carbon atoms, and more preferably an alkyl(meth)acrylate that has an alkyl group having from 1 to 8 carbon atoms. Examples of the alkyl(meth)acrylate include methyl(meth)acrylate, ethyl(meth)acrylate, propyl(meth)acrylate, butyl(meth)acrylate, pentyl(meth)acrylate, hexyl(meth)acrylate, heptyl(meth)acrylate, octyl(meth)acrylate, 2-ethylhexyl(meth)acrylate, nonyl(meth)acrylate, decyl(meth)acrylate, undecyl(meth)acrylate, and dodecyl(meth)acrylate. These compounds may be used singly, or in any combination of two or more kinds thereof.

In case in which the binder polymer has the structural unit derived from alkyl(meth)acrylate ester, the content ratio thereof based on the total mass (100% by mass) of the polymerizable monomer for constituting the binder polymer is preferably from 1% by mass to 30% by mass, more preferably from 1% by mass to 20% by mass, and still more preferably from 2% by mass to 10% by mass, in terms of excellent release property, resolution, and adhesiveness of the resulting resist pattern. In terms of excellent release property, the content ratio is preferably 1% by mass or more, and more preferably 2% by mass or more. In terms of excellent resolution and adhesiveness, the content ratio is preferably 30% by mass or less, more preferably 20% by mass or less, and still more preferably from 10% by mass or less.

The acid value of the binder polymer is preferably from 90 mg KOH/g to 250 mg KOH/g, more preferably from 100 mg KOH/g to 240 mg KOH/g, still more preferably from 120 mg KOH/g to 235 mg KOH/g, and even more preferably from 130 mg KOH/g to 230 mg KOH/g, in terms of excellent developability and adhesiveness of the resulting resist pattern. In terms of reducing developing time, the acidic value is preferably 90 mg KOH/g or more, more preferably 100 mg KOH/g or more, still more preferably 120 mg KOH/g or more, and even more preferably 130 mg KOH/g or more. In terms of achieving the sufficient adhesiveness of the cured product of the photosensitive resin composition, the acidic value is preferably 250 mg KOH/g or less, more preferably 240 mg KOH/g or less, still more preferably 235 mg KOH/g or less, and even more preferably 230 mg KOH/g or less. In a case in which development is carried out with a solvent, it is preferable to control the amount of the polymerizable monomer (monomer) having a carboxy group such as (meth)acrylic acid to be small.

The weight-average molecular weight (Mw) of the binder polymer measured by gel permeation chromatography (GPC) (calculated based on a calibration curve using polystyrene standards) is preferably from 10,000 to 200,000, more preferably from 15,000 to 100,000, still more preferably from 20,000 to 80,000, and even more preferably from 23,000 to 60,000, in terms of excellent developability and adhesiveness. In terms of excellent developability, the weight-average molecular weight is preferably 200,000 or less, more preferably 100,000, still more preferably 80,000, and even more preferably 60,000. In terms of excellent adhesiveness, the weight-average molecular weight is preferably 10,000 or more, more preferably 15,000 or more, still more preferably 23,000 or more, and even more preferably 30,000 or more.

The dispersivity (weight-average molecular weight/number-average molecular weight) of the binder polymer is preferably 3.0 or less, more preferably 2.8 or less, and still more preferably 2.5 or less, in terms of excellent resolution and adhesiveness.

The binder polymer may have, in the molecule thereof, a characteristic group with sensitivity to light having a wavelength in a range of from 340 nm to 430 nm if necessary. Examples of the characteristic group include a group obtained by removing at least one hydrogen atom from the sensitizing dye described below.

As the component (A), only one type of binder polymer may be used singly, or two or more types of binder polymers may be used in any combination.

The content of the component (A) in the photosensitive resin composition is preferably from 30 parts by mass to 70 parts by mass, more preferably from 35 parts by mass to 65 parts by mass, and still more preferably from 40 parts by mass to 60 parts by mass, with respect to 100 parts by mass of the total amount of the component (A) and the component (B), in terms of excellent film formability, sensitivity, and resolution. In terms of film (photosensitive resin composition layer) formability, the content is preferably 30 parts by mass or more, more preferably 35 parts by mass or more, and still more preferably 40 parts by mass or more. In terms of obtaining sufficient sensitivity and resolution, the content is preferably 70 parts by mass or less, more preferably 65 parts by mass or less, and still more preferably 60 parts by mass or less.

Component (B): Photopolymerizable Compound

Hereinbelow, the photopolymerizable compound (hereinafter, sometimes referred to as “component (B)”) is explained. The photopolymerizable compound, the component (B), includes as an essential component at least one first bisphenol di(meth)acrylate (hereinafter, sometimes referred to as “specific polymerizable compound”) that has an ethyleneoxy group and a propyleneoxy group, in which the number of the structural unit of the ethyleneoxy group is from 1 to 20 and the number of the structural unit of the propyleneoxy group is from 2 to 7, and in which the total number of structural unit of the ethyleneoxy group and the propyleneoxy group is more than 10. If needed, the component (B) may further include a photopolymerizable compound other than the first bisphenol di(meth)acrylate.

In is assumed that the specific polymerizable compound having a propyleneoxy group exhibits a low degree of swelling since the molecular motion in the cross-linked network after curing is suppressed, and therefore the resulting resist pattern has excellent resolution property. In addition, it is assumed that the specific polymerizable compound has the ethyleneoxy group that is a more flexible partial structure, and therefore flexibility of the resulting resist pattern is further improved.

In the specific polymerizable compound, the total number of the structural unit of the propyleneoxy group per molecule is from 2 to 7. Here, the number of the structural unit represents the addition number of the propyleneoxy group in the molecule. Therefore, the number of the structural unit indicates integer value with respect to a single molecule, while it represents a rational number, which is an average value, with respect to a group of plural kinds of molecules.

In the specific polymerizable compound, the total number of the structural unit of the ethyleneoxy group per molecule is from 1 to 20. Here, the number of the structural unit represents a degree of addition of the ethyleneoxy group in the molecule. Therefore, the number of the structural unit indicates integer value with respect to a single molecule, while it represents a rational number, which is an average value, with respect to a group of plural kinds of molecules.

The total number of the structural unit of the propyleneoxy group in the specific polymerizable compound is 2 or more, and preferably 3 or more, in terms of excellent resolution property of the resist. In terms of excellent developability, the total number is preferably 5 or less.

The total number of the structural unit of the ethyleneoxy group in the specific polymerizable compound is preferably 4 or more, more preferably 6 or more, and still more preferably 8 or more, in terms of excellent developability. In terms of resolution, the total number is preferably 16 or less, and more preferably 14 or less.

The specific polymerizable compound is preferably a compound represented by the following Formula (4a).

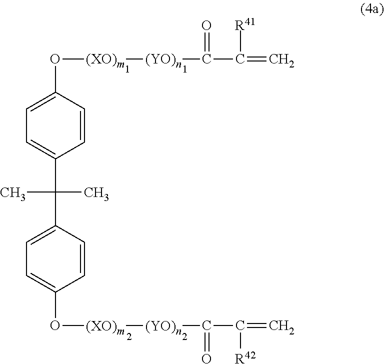

In Formula (4a), each of R⁴¹ and R⁴² independently represents a hydrogen atom or a methyl group. Each of XO and YO independently represents an ethyleneoxy group or a propyleneoxy group. Each of (XO)m₁, (XO)m₂, (YO)n₁, and (YO)n₂ independently represents a (poly)ethyleneoxy group or a (poly)propyleneoxy group. Each of m₁, m₂, n₁, and n₂ independently represents 0 to 20. When XO represents an ethyleneoxy group and YO represents a propyleneoxy group, m₁+m₂ is from 1 to 20, and n₁+n₂ is form 2 to 7. When XO represents a propyleneoxy group and YO represents an ethyleneoxy group, m₁+m₂ is from 2 to 7, and n₁+n₂ is form 1 to 20. m₁+m₂+n₁+n₂ is more than 10. Each of m₁, m₂, n₁, and n₂ represents the number of the structural unit. Therefore, the number of the structural unit indicates integer value with respect to a single molecule, while it represents a rational number, which is an average value, with respect to a group of plural kinds of molecules. Hereinbelow, the same applies to the number of the structural unit.

Examples of commercially available products of the above compound include 2,2-bis(4-(methacryloxy dodecaethoxy tetrapropoxy)phenyl) propane (“FA-3200MY” manufactured by Hitachi Chemical Co., Ltd).

From the viewpoint of reducing degree of swelling by suppressing molecular motion in the cross-linked network after curing, the content of the specific polymerizable compound in the photosensitive resin composition is preferably from 1 part by mass to 60 parts by mass, more preferably from 5 part by mass to 50 parts by mass, and still more preferably from 10 part by mass to 40 parts by mass, with respect to 100 parts by mass of the total amount of the component (A) and the component (B). In terms of excellent bottom curing property of the resist, the content is preferably 30 parts by mass or less, more preferably 25 parts by mass or less, and still preferably 23 parts by mass or less.

The photosensitive resin composition may include, as the component (B), an additional photopolymerizable compound other than the specific polymerizable compound. The additional photopolymerizable compound is not particularly limited as long as it is a compound capable of photopolymerizing. The additional photopolymerizable compound is preferably a compound having an ethylenically unsaturated bond. Examples of the compound having an ethylenically unsaturated bond include a compound having one ethylenically unsaturated bond in the molecule, a compound having two ethylenically unsaturated bonds in the molecule, a compound having three or more ethylenically unsaturated bonds in the molecule.

In a case in which the component (B) includes the additional photopolymerizable compound, the content of the additional photopolymerizable compound in the component (B) with respect to 100 parts by mass of the total mass of the component (B) is preferably from 2 parts by mass to 60 parts by mass, more preferably from 6 parts by mass to 50 parts by mass, and still more preferably from 10 parts by mass to 40 parts by mass, from the viewpoint of suppressing swelling physically via the bulky configuration of the cross-linked network.

It is preferable that the component (B) includes, as the additional photopolymerizable compound, at least one compound having two ethylenically unsaturated bonds in the molecule. In a case in which the component (B) includes, as the additional photopolymerizable compound, the compound having two ethylenically unsaturated bonds in the molecule, the content thereof is preferably from 5 parts by mass to 60 parts by mass, more preferably from 5 parts by mass to 55 parts by mass, and still more preferably 10 parts by mass to 50 parts by mass, with respect to 100 parts by mass of the total amount of the component (A) and the component (B).

Examples of the compound having two ethylenically unsaturated bonds in the molecule include a bisphenol di(meth)acrylate compound having a structure different from the specific polymerizable compound; a hydrogenated bisphenol A di(meth)acrylate compound; a di(meth)acrylate compound having a urethane bond in the molecule; a polyalkylene glycol di(meth)acrylate having both a (poly)ethyleneoxy group and a (poly)propyleneoxy group in the molecule, and trimethylolpropane di(meth)acrylate.

From the viewpoint of improving resolution and release property, the component (B) preferably includes, as the additional photopolymerizable compound, at least one compound having two ethylenically unsaturated bonds in the molecule selected from the group consisting of a bisphenol di(meth)acrylate compound having a structure different from the specific polymerizable compound, a hydrogenated bisphenol A di(meth)acrylate compound, and a polyalkylene glycol di(meth)acrylate having both a (poly)ethyleneoxy group and a (poly)propyleneoxy group in the molecule, more preferably includes at least one bisphenol di(meth)acrylate compound having a structure different from the specific polymerizable compound, and still more preferably includes a bisphenol di(meth)acrylate compound having a structure different from the specific polymerizable compound, the bisphenol di(meth)acrylate which has an ethyleneoxy group, and in which the number of structural unit of the ethyleneoxy group is 8 or less (hereinafter, sometimes referred to as “second bisphenol di(meth)acrylate compound”).

Examples of the bisphenol di(meth)acrylate compound having a structure different from the specific polymerizable compound include a compound represented by the following Formula (4b).

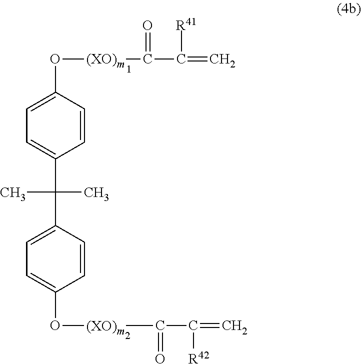

In Formula (4b), each of R⁴¹ and R⁴² independently represents a hydrogen atom or a methyl group. Each of XO represents an ethyleneoxy group; and each of (XO)m₁ and (XO)m₂ represents a (poly)ethyleneoxy group. Each of m₁ and m₂ independently represents the number of a structural unit included therein, and independently represents from 0 to 40.

In terms of excellent resolution property, it is preferable to use a compound in Formula (4b) in which each of m₁ and m₂ independently represents from 0 to 8 and m₁+m₂ is 8 or less; and more preferable to use a compound in Formula (4b) in which each of m₁ and m₂ independently represents from 0 to 6 and m₁+m₂ is 6 or less. In terms of flexibility, the lower limit of m₁+m₂ is preferably 2 or more, and more preferably 4 or more.

Examples of commercially available product of the compound represented by Formula (4b) include 2,2-bis(4-(methacryloxydiethoxy)phenyl)propane (e.g., “FA-324M” manufactured by Hitachi Chemical Co., Ltd), 2,2bis(4-(methacryloxypentaethoxy)phenyl)propane (e.g., “BPE-500” manufactured by Shin-Nakamura Chemical Co., Ltd., “FA-321M”, manufactured by Hitachi Chemical Co., Ltd), and 2,2bis(4-(methacryloxypentadecaethoxy)phenyl)propane (e.g., “BPE-1300” manufactured by Shin-Nakamura Chemical Co., Ltd). These compounds may be used singly, or in any combination of two or more kinds thereof.

In a case in which the photosensitive resin composition further includes, as the component (B), the bisphenol di(meth)acrylate compound other than the specific polymerizable compound, the content thereof is preferably from 1 part by mass to 50 parts by mass, more preferably from 5 parts by mass to 50 parts by mass, and still more preferably from 10 parts by mass to 45 parts by mass, with respect to 100 parts by mass of the total amount of the component (A) and the component (B).

Examples of the hydrogenated bisphenol A di(meth)acrylate compound include 2,2-bis(4-(methacryloxypentaethoxy)cyclohexyl)propane. In a case in which the photosensitive resin composition further includes, as the component (B), the hydrogenated bisphenol A di(meth)acrylate compound, the content thereof is preferably from 1 part by mass to 50 parts by mass, and more preferably from 5 parts by mass to 40 parts by mass, with respect to 100 parts by mass of the total amount of the component (A) and the component (B).

It is preferable that the component (B) includes, as the additional photopolymerizable compound, at least one polyalkylene glycol di(meth)acrylate, from the viewpoint of improving flexibility of the resist pattern. In a case in which the photosensitive resin composition includes the polyalkylene glycol di(meth)acrylate, the content thereof is preferably from 5 parts by mass to 30 parts by mass, and more preferably from 10 parts by mass to 25 parts by mass, with respect to 100 parts by mass of the total amount of the component (A) and the component (B).

The polyalkylene glycol di(meth)acrylate is preferably a polyalkylene glycol di(meth)acrylate having both of a (poly)ethyleneoxy group and a (poly)propyleneoxy group in the molecule. In the molecule of the polyalkylene glycol di(meth)acrylate, the (poly)ethyleneoxy group and the (poly)propyleneoxy group may be present as continuous blocks or present randomly. Here, the propyleneoxy group of the (poly)propyleneoxy group may be either a n-propyleneoxy group or an isopropyleneoxy group. In the (poly)isopropyleneoxy group, the oxygen atom may bind to the secondary carbon atom of the propylene group, or the primary carbon atom thereof.

The polyalkylene glycol di(meth)acrylate may include (poly)n-butyleneoxy group, (poly)isobutyleneoxy group, (poly)n-pentyleneoxy group, or (poly)hexyleneoxy group, or the constitutional isomer thereof, such as (poly)alkyleneoxy group having from about 4 to about 6 carbon atoms.

The component (B) may include, as the additional photopolymerizable compound, at least one photopolymerizable compound having three or more ethylenically unsaturated bonds in the molecule thereof.

Examples of the compound having three or more ethylenically unsaturated bonds in the molecule thereof include trimethylolpropane tri(meth)acrylate, an EO-modified trimethylolpropane tri(meth)acrylate (in which the number of structural units of the ethyleneoxy group is from 1 to 5), a PO-modified trimethylolpropane tri(meth)acrylate, an EO, PO-modified trimethylolpropane tri(meth)acrylate, tetramethylolmethane tri(meth)acrylate, tetramethylolmethane tetra(meth)acrylate, pentaerythritol tri(meth)acrylate, and dipentaerythritol hexa(meth)acrylate. These compounds may be used singly, or in combination of two or more kinds thereof.

Examples of commercially available product of the compound having three or more ethylenically unsaturated bonds include tetramethylolmethane triacrylate (e.g., “A-TMM-3” manufactured by Shin-Nakamura Chemical Co., Ltd.), EO-modified trimethylolpropane trimethacrylate (e.g., “TMPT21E”, “TMPT30E” manufactured by Hitachi Chemical Co., Ltd), pentaerythritol triacrylate (e.g., “SR444” manufactured by Sartomer), dipentaerythritol hexaacrylate (e.g., “A-DPH” manufactured by Shin-Nakamura Chemical Co., Ltd.), and ethoxylated pentaerythritol tetraacrylate (e.g., “ATM-35E” manufactured by Shin-Nakamura Chemical Co., Ltd).

In a case in which the component (B) includes, as the additional photopolymerizable compound, the compound having three or more ethylenically unsaturated bonds, the content thereof is preferably from 3 parts by mass to 30 parts by mass, more preferably from 5 parts by mass to 25 parts by mass, and still more preferably from 5 parts by mass to 20 parts by mass, with respect to 100 parts by mass of the total amount of the component (A) and the component (B), from the viewpoint of improving the balance between resolution, adhesiveness, resist shape, and release property after curing.

The component (B) may include, as the additional photopolymerizable compound, a compound having one ethylenically unsaturated bond in the molecule, in terms of improving the balance between the resolution, adhesiveness, resist shape, and release property after curing of the resulting resist pattern, or suppressing the occurrence of scum.

Examples of the compound having one ethylenically unsaturated bond in the molecule include nonylphenoxy polyethyleneoxy acrylate, a phthalic acid compound, and an alkyl (meth)acrylate. Among these, from the viewpoint of improving the balance between the resolution, adhesiveness, resist shape, and release property after curing of the resulting resist pattern, it is preferable to include nonylphenoxy polyethyleneoxy acrylate or a phthalic acid compound.

In a case in which the component (B) includes, as the additional photopolymerizable compound, the photopolymerizable compound having one ethylenically unsaturated bond in the molecule, the content thereof is preferably from 1 part by mass to 20 parts by mass, more preferably from 3 parts by mass to 15 parts by mass, and still more preferably from 5 parts by mass to 12 parts by mass, with respect to 100 parts by mass of the total amount of the component (A) and the component (B).

The total content of the component (B) in the photosensitive resin composition is preferably from 30 parts by mass to 70 parts by mass, more preferably from 35 parts by mass to 65 parts by mass, and still more preferably from 35 parts by mass to 50 parts by mass, with respect to 100 parts by mass of the total amount of the component (A) and the component (B). In a case in which the content is 30 parts by mass or more, sufficient sensitivity of the photosensitive resin composition and sufficient resolution of the resulting resist pattern can be easily obtained. In a case in which the content is 70 parts by mass or less, the film (photosensitive resin composition layer) can be easily formed and the excellent resist shape can be easily obtained.

Component (C): Photopolymerization Initiator

The photosensitive resin composition includes, as component (C), at least one photopolymerization initiator. The photopolymerization initiator as the component (C) is not particularly limited, and appropriately selected from conventionally employed photopolymerization initiators. Examples of the photopolymerization initiator include aromatic ketones such as benzophenone, 2-benzyl-2-dimethylamino-1-(4-morpholinophenyl)-butanone-1, or 2-methyl-1-[4-(methylthio)phenyl]-2-morpholino-propanone-1; quinones such as an alkylanthraquinone; benzoin ether compounds such as a benzoin alkyl ether; benzoin compounds such as benzoin and an alkyl benzoin; benzyl derivatives such as benzyl dimethyl ketal; 2,4,5-triarylimidazole dimers such as 2-(2-chlorophenyl)-4,5-diphenylimidazole dimer, or 2-(2-fluorophenyl)-4,5-diphenylimidazole dimer; and acridine derivatives such as 9-phenylacridine or 1,7-(9,9′-acridinyl)heptane. These compounds may be used singly, or in combination of two or more kinds thereof.

In terms of improving the sensitivity of the photosensitive resin composition and the adhesiveness of the resulting resist pattern, the component (C) preferably includes at least one 2,4,5-triarylimidazole dimer, and more preferably includes 2-(2-chlorophenyl)-4,5-diphenylimidazole dimer. The structure of the 2,4,5-triarylimidazole dimer may be symmetric or asymmetric.

The content of the component (C) in the photosensitive resin composition is preferably from 0.1 parts by mass to 10 parts by mass, more preferably from 1 part by mass to 7 parts by mass, still more preferably from 2 parts by mass to 6 parts by mass, and even more preferably from 3 parts by mass to 5 parts by mass, with respect to 100 parts by mass of the total amount of the component (A) and the component (B). In a case in which the content of the component (C) is 0.1 parts by mass or more, excellent sensitivity, resolution, or adhesiveness can be easily obtained. In a case in which the content is 10 parts by mass or less, excellent resist shape can be easily obtained.

Component (D): Sensitizing Dye

The photosensitive resin composition according to the present embodiment preferably includes, as component (D), at least one sensitizing dye selected form the group consisting of a pyrazoline derivative and a bis-alkoxy anthracene. The sensitizing dye as the component (D) may be used singly, or in any combination of two or more kinds thereof.

In particular, in a case in which exposure of the photosensitive resin composition layer is carried out using active light rays have a wavelength of from 340 nm to 430 nm, the component (D) preferably includes at least one sensitizing dye selected form the group consisting of a pyrazoline derivative and a bis-alkoxy anthracene.

The pyrazoline compound is preferably at least one selected form the group consisting of compounds represented by the following Formula (8) and compounds represented by the following Formula (9).

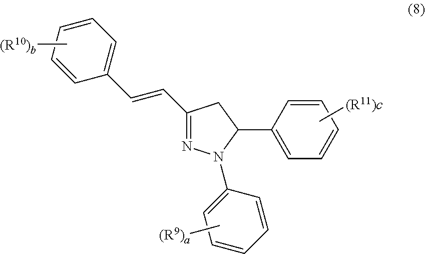

In Formula (8), each of R⁹ to R¹¹ independently represents a linear or branched alkyl group having from 1 to 12 carbon atoms, a linear or branched alkoxy group having from 1 to 10 carbon atoms, an aryl group having from 6 to 8 carbon atoms, or a halogen atom. Each of a, b and c independently represents an integer of 0 to 5, and the sum of a, b and c is from 1 to 6. When the sum of a, b and c is 2 or more, plural R⁹ to R¹¹ may be the same as or different from one another.

In Formula (8), at least one of R⁹ to R¹¹ represents preferably a linear or branched alkyl group having from 1 to 12 carbon atoms or a linear or branched alkoxy group having from 1 to 10 carbon atoms, more preferably a linear or branched alkyl group having from 1 to 4 carbon atoms, a linear or branched alkoxy group having from 1 to 4 carbon atoms, or a phenyl group, and still more preferably a tert-butyl group, an isopropyl group, a methoxy group, or an ethoxy group.

The pyrazoline compound represented by Formula (8) used here is not particularly limited, and specific examples thereof include pyrazoline compounds in which a=0 in Formula (8), such as 1-phenyl-3-(4-isopropylstyryl)-5-(4-isopropylphenyl)-pyrazoline, 1-phenyl-3-(4-tert-butyl-styryl)-5-(4-tert-butylphenyl)-pyrazoline, 1-phenyl-3-(4-methoxystyryl)-5-(4-methoxyphenyl)-pyrazoline, 1-phenyl-3-(3,5-dimethoxystyryl)-5-(3,5-dimethoxyphenyl)-pyrazoline, 1-phenyl-3-(3,4-dimethoxystyryl)-5-(3,4-dimethoxyphenyl)-pyrazoline, 1-phenyl-3-(2,6-dimethoxystyryl)-5-(2,6-dimethoxyphenyl)-pyrazoline, 1-phenyl-3-(2,5-dimethoxystyryl)-5-(2,5-dimethoxyphenyl)-pyrazoline, 1-phenyl-3-(2,3-dimethoxystyryl)-5-(2,3-dimethoxyphenyl)-pyrazoline, or 1-phenyl-3-(2,4-dimethoxystyryl)-5-(2,4-dimethoxyphenyl)-pyrazoline.

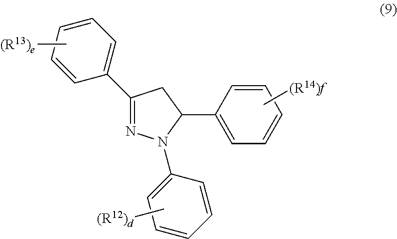

In Formula (9), each of R¹² to R¹⁴ independently represents a linear or branched alkyl group having from 1 to 12 carbon atoms, a linear or branched alkoxy group having from 1 to 10 carbon atoms, an aryl group having from 6 to 8 carbon atoms, or a halogen atom. Each of d, e and f independently represents an integer of 0 to 5, and the sum of d, e and f is from 1 to 6. When the sum of d, e and f is 2 or more, plural R¹² to R¹⁴ may be the same as or different from one another.

In Formula (9), at least one of R¹² to R¹⁴ represents preferably a linear or branched alkyl group having from 1 to 12 carbon atoms, a linear or branched alkoxy group having from 1 to 10 carbon atoms, or a phenyl group, more preferably a linear or branched alkyl group having from 1 to 4 carbon atoms, a linear or branched alkoxy group having from 1 to 4 carbon atoms, or a phenyl group, and still more preferably a tert-butyl group, an isopropyl group, a methoxy group, an ethoxy group, or a phenyl group.

The pyrazoline compound represented by Formula (9) used here is not particularly limited, and examples thereof include pyrazoline compounds in which d=0 in Formula (9), such as 1-phenyl-3,5-bis(4-tert-butylphenyl)-pyrazoline, 1-phenyl-3,5-bis(4-methoxyphenyl)-pyrazoline, 1-phenyl-3-(4-methoxyphenyl)-5-(4-tert-butylphenyl)-pyrazoline, 1-phenyl-3-(4-tert-butylphenyl)-5-(4-methoxyphenyl)-pyrazoline, 1-phenyl-3-(4-isopropylphenyl)-5-(4-tert-butylphenyl)-pyrazoline, 1-phenyl-3-(4-tert-butylphenyl)-5-(4-isopropylphenyl)-pyrazoline, 1-phenyl-3-(4-methoxyphenyl)-5-(4-isopropylphenyl)-pyrazoline, 1-phenyl-3-(4-isopropylphenyl)-5-(4-methoxyphenyl)-pyrazoline, 1,5-diphenyl-3-(4-tert-butylphenyl)-pyrazoline, 1,3-diphenyl-5-(4-tert-butylphenyl)-pyrazoline, 1,5-diphenyl-3-(4-isopropylphenyl)-pyrazoline, 1,3-diphenyl-5-(4-isopropylphenyl)-pyrazoline, 1,5-diphenyl-3-(4-methoxyphenyl)-pyrazoline, 1,3-diphenyl-5-(4-methoxyphenyl)-pyrazoline, 1-phenyl-3,5-bis(4-tert-butylphenyl)-pyrazoline, or 1,5-diphenyl-3-(4-tert-butylphenyl)-pyrazoline; and pyrazoline compounds in which e=1 and R¹³=a phenyl group in Formula (9), such as 1-phenyl-3-(4-biphenyl)-5-(4-tert-butylphenyl)-pyrazoline, or 1-phenyl-3-(4-biphenyl)-5-(4-tert-octylphenyl)-pyrazoline.

The bis-alkoxy anthracene compound preferably includes a compound represented by the following Formula (10).

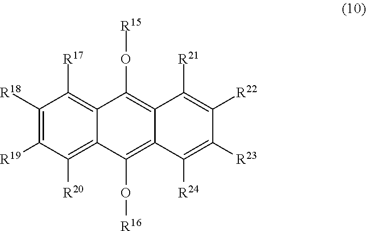

In Formula (10), each of R¹⁵ and R¹⁶ independently represents an alkyl group having from 1 to 20 carbon atoms, a cycloalkyl group having from 5 to 12 carbon atoms, a phenyl group, a benzyl group, an alkanoyl group having from 2 to 12 carbon atoms, or a benzoyl group. Each of R¹⁷ to R²⁴ independently represents a hydrogen atom, an alkyl group having from 1 to 12 carbon atoms, a halogen atom, a cyano group, a carboxy group, a phenyl group, an alkoxycarbonyl group having from 2 to 6 carbon atoms, an aryloxy group having from 6 to 8 carbon atoms, or a benzoyl group.

Preferable examples of R¹⁵ and R¹⁶ in Formula (10) include a methyl group, an ethyl group, a propyl group, a butyl group, a pentyl group, and a hexyl group. Examples of the combination of R¹⁵ and R¹⁶ include a combination of ethyl groups, a combination of propyl groups, and a combination of butyl groups.

Examples of R¹⁷ to R²⁴ include a hydrogen atom, a methyl group, an ethyl group, a propyl group, a butyl group, a pentyl group, a hexyl group, a propenyl group, a butenyl group, a pentenyl group, a hexenyl group, a heptenyl group, an ethoxycarbonyl group, a hydroxyethoxycarbonyl group, and a phenoxy group. Examples of the combination of R¹⁷ to R²⁴ include: all of R¹⁷ to R²⁴ represent hydrogen atoms; one of R¹⁷ to R²⁴ represents a methyl group, an ethyl group, a propyl group, a butyl group, a pentyl group, a hexyl group, a propenyl group, a butenyl group, a pentenyl group, a hexenyl group, a heptenyl group, an ethoxycarbonyl group, a hydroxyethoxycarbonyl group, or a phenoxy group, and the others represent hydrogen atoms; and two of R¹⁷ to R²⁴ each independently represent a methyl group, an ethyl group, a propyl group, a butyl group, a pentyl group, a hexyl group, a propenyl group, a butenyl group, a pentenyl group, a hexenyl group, a heptenyl group, an ethoxycarbonyl group, a hydroxyethoxycarbonyl group, or a phenoxy group, and the others represent hydrogen atoms.

It is preferable that each of R¹⁵ and R¹⁶ independently represents an alkyl group having from 1 to 4 carbon atoms. Each of R¹⁷ R¹⁸, R¹⁹, R²⁰, R²¹ R²², R²³ and R²⁴ preferably represents a hydrogen atom.

Specific examples of the compound represented by Formula (10) include 9,10-dimethoxy anthracene, 9,10-diethoxy anthracene, and 9,10-dibuthoxy anthracene.

The content of the component (D) in the photosensitive resin composition is preferably from 0.01 parts by mass to 10 parts by mass, more preferably from 0.05 parts by mass to 5 parts by mass, and still more preferably from 0.1 parts by mass to 3 parts by mass, with respect to 100 parts by mass of the total amount of the component (A) and the component (B). In a case in which the content is 0.01 parts by mass or more, sufficient sensitivity and resolution can be easily obtained. In a case in which the content is 10 parts by mass or less, sufficiently excellent resist shape can be easily obtained.

Component (E): Amine Compound

The photosensitive resin composition preferably includes, as component (E), at least one amine compound. Examples of the amine compound include bis[4-(dimethylamino)phenyl]methane, bis[4-(diethylamino)phenyl]methane, and Leucocrystal Violet. These compounds may be used singly, or in combination of two or more kinds thereof.

In a case in which the photosensitive resin composition includes the component (E), the content thereof is preferably from 0.01 parts by mass to 10 parts by mass, more preferably from 0.05 parts by mass to 5 parts by mass, and still more preferably from 0.1 parts by mass to 2 parts by mass, with respect to 100 parts by mass of the total amount of the component (A) and the component (B). In a case in which the content is 0.01 parts by mass or more, sufficient sensitivity can be easily obtained. In a case in which the content is 10 parts by mass or less, precipitation of excessive component (E) as a foreign material after film formation can be easily suppressed.

Other Component

The photosensitive resin composition may include, if necessary, a photopolymerizable compound (such as an oxetane compound) having at least one cation polymerizable cyclic ether group in the molecule thereof; a cation polymerization initiator; a dye such as Malachite Green, Victoria Pure Blue, Brilliant Green, or Methyl Violet; a photochromic agent such as tribromophenylsulfone, diphenylamine, benzylamine, triphenylamine, diethylaniline, or 2-chloroaniline; a thermal development inhibitor; a plasticizer such as 4-toluenesulfonamide; a pigment; a filler; an antifoaming agent; a flame retardant; a stabilizing agent; a tackifier; a leveling agent; a release promoter; an antioxidant; perfume; an imaging agent; a thermal crosslinking agent; or the like. These compounds may be used singly, or in combination of two or more kinds thereof. In a case in which the photosensitive resin composition may include the other component, the content (total content if plural components are contained) is preferably from about 0.01 parts to about 20 parts by mass, with respect to 100 parts by mass of the total amount of the component (A) and the component (B).

Solution of Photosensitive Resin Composition

The photosensitive resin composition according to the present embodiment may further include at least one organic solvent. Examples of the organic solvent include alcohol solvents such as methanol or ethanol; ketone solvents such as acetone, or methyl ethyl ketone; glycol ethers such as methylcellosolve, ethylcellosolve, or propyleneglycol monomethyl ether; aromatic hydrocarbon solvents such as toluene; and aprotic polar solvents such as N,N-dimethylformamide. These solvents may be used singly, or in combination of two or more kinds thereof. The content of the organic solvent in the photosensitive resin composition can be appropriately selected depending on the purpose or the like. For example, the organic solvent may be used to give a solution with a solid content of from about 30% by mass to about 60% by mass. Hereinbelow, the photosensitive resin composition containing the organic solvent is sometimes referred to as “coating solution”.

The photosensitive resin composition layer, which is a coating film of the photosensitive resin composition, can be formed by applying the coating solution onto a surface of a support film described below or a metal plate and drying the resultant. The metal plate is not particularly limited and can be appropriately selected depending on the purpose or the like. Examples of the metal plate include metal plates of copper, a copper-based alloy, nickel, chromium, iron, and an iron-based alloy such as stainless steel. Preferable examples of the metal plate include copper, a copper-based alloy, and an iron-based alloy.

The thickness of the resulting photosensitive resin composition layer is not particularly limited and can be appropriately selected depending on the intended use or the like. For example, the thickness of the photosensitive resin composition layer is preferably from about 1 μm to about 100 μm after drying. In a case in which the photosensitive resin composition layer is formed on the metal plate, the surface opposite the metal plate in the photosensitive resin composition layer may be covered with a protective film. Examples of the protective film include polymer films such as polyethylene or polypropylene.

The photosensitive resin composition can be applied to the formation of the photosensitive resin composition layer of the photosensitive element described below. That is, another embodiment of the present invention is the application of the photosensitive resin composition to the photosensitive element, the photosensitive resin composition including: the component (A): the binder polymer that has a structural unit derived from (meth)acrylic acid, a structural unit derived from styrene or α-methyl styrene, and a structural unit derived from benzyl (meth)acrylate; the component (B): the photopolymerizable compound including the first bisphenol di(meth)acrylate that has an ethyleneoxy group and a propyleneoxy group, in which a number of structural units of the ethyleneoxy group is from 1 to 20 and a number of structural units of the propyleneoxy group is from 2 to 7, and in which a total number of structural units of the ethyleneoxy group and the propyleneoxy group is more than 10; and the component (C): the photopolymerization initiator. The photosensitive resin composition according to another embodiment of the present invention can be used in the method of forming a resist pattern described below. That is, yet another aspect of the present invention is the application of the photosensitive resin composition to the method of forming a resist pattern, the photosensitive resin composition including: the component (A): the binder polymer that has a structural unit derived from (meth)acrylic acid, a structural unit derived from styrene or α-methyl styrene, and a structural unit derived from benzyl (meth)acrylate; the component (B): the photopolymerizable compound including the first bisphenol di(meth)acrylate that has an ethyleneoxy group and a propyleneoxy group, in which a number of structural units of the ethyleneoxy group is from 1 to 20 and a number of structural units of the propyleneoxy group is from 2 to 7, and in which a total number of structural units of the ethyleneoxy group and the propyleneoxy group is more than 10; and the component (C): the photopolymerization initiator.

Photosensitive Element

The photosensitive element according to the present invention includes a support film and a photosensitive resin composition layer, which is a coating film of the above-described photosensitive resin composition, provided on the support film. In the coating film, the photosensitive resin composition is in an uncured state. The photosensitive element may include, if necessary, other layer such as a protective film.

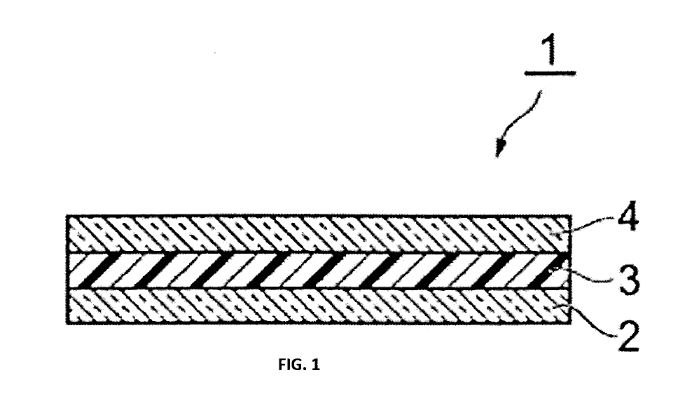

FIG. 1 shows an embodiment of a photosensitive element. In a photosensitive element 1 shown in FIG. 1, a support film 2, a photosensitive resin composition layer 3 that is a coating film of the photosensitive resin composition, and a protective film 4 are layered in this order. The photosensitive element 1 can be obtained, for example, as follows. That is, a coating solution, which is the photosensitive resin composition containing an organic solvent, is applied onto the support film 2 to form a coating layer, and the resultant is dried to form the photosensitive resin composition layer 3. The surface opposite the support film 2 in the photosensitive resin composition layer 3 is then covered with the protective film 4, thereby obtaining the photosensitive element 1 according to the present embodiment provided with the support film 2, the photosensitive resin composition layer 3 formed on the support film 2, the protective film 4 layered on the photosensitive resin composition layer 3. The photosensitive element 1 is not necessarily provided with the protective film 4.

As the support film, a polymer film having heat resistance and solvent resistance, such as polyester (e.g., polyethylene terephthalate), polypropylene, or polyethylene may be used.

The thickness of the support film (polymer film) is preferably from 1 μm to 100 μm, more preferably from 5 μm to 50 μm, and still more preferably from 5 μm to 30 μm. In a case in which the thickness of the support film is 1 μm or more, tearing of the support film during releasing the support film can be suppressed. In a case in which the thickness is 100 μm or less, deterioration in resolution can be suppressed.

The protective film is preferably one whose adhesive force with respect to the photosensitive resin composition layer is lower than the adhesive force of the support film with respect to the photosensitive resin composition layer. The protective film is preferably a low-fisheye film. Here, the term “fisheye” mean inclusion of a foreign material, an undissolved material, an oxidation degraded material, or the like of a raw material that has been taken into the film during manufacture of the film by thermal melting, kneading, extrusion, biaxially-stretching, or casting the raw material. That is, “low-fisheye” means that the film contains few foreign materials.

More specifically, the protective film used here may be a polymer film having heat resistance and solvent resistance, such as polyester including polyethylene terephthalate, polypropylene, or polyethylene. Examples of commercially available product thereof include ALPHAN MA-410 and E-200 manufactured by Oji Paper Co., Ltd.; a polypropylene film manufactured by Shin-Etsu Film Co., Ltd.; and a polyethylene terephthalate film of PS series such as PS-25 manufactured by Teijin Limited. The protective film 4 may be the same as the support film 2.

The thickness of the protective film is preferably from 1 μm to 100 μm, more preferably from 5 μm to 50 μm, still more preferably from 5 μm to 30 μm, and even more preferably from 15 μm to 30 μm. In a case in which the thickness of the protective film is 1 μm or more, tearing of the protective film during laminating the photosensitive resin composition layer and the support film on the substrate while releasing the protective film can be suppressed. In a case in which the thickness is 100 μm or less, excellent handleability and low-cost can be achieved.

More specifically, the photosensitive element according to the present embodiment can be manufactured, for example, as follows. That is, the photosensitive element can be manufactured by the manufacture method that includes a process of preparing a coating solution in which the component (A): the binder polymer, the component (B): the photopolymerizable compound, and the photopolymerization initiator (C) are dissolved in the organic solvent; a process of forming a coating layer by applying the coating solution to a support (a support film); and a process of drying the resultant to form the photosensitive resin composition layer.

The coating of the solution of the photosensitive resin composition to the support film may be carried out by a known method such as roll coating, comma coating, gravure coating, air knife coating, die coating, or bar coating.

The drying condition of the coating layer is not particularly limited as long as at least a part of the organic solvent can be removed from the coating layer. The drying is preferably carried out at from 70° C. to 150° C. for about 5 minutes to about 30 minutes. The amount of residual organic solvent in the photosensitive resin composition layer after drying is preferably 2% by mass or less from the viewpoint of preventing diffusion of the organic solvent in subsequent processes.

The thickness of the photosensitive resin composition layer in the photosensitive element can be appropriately selected depending on the intended use. The post-drying thickness is preferably from 1 μm to 100 μm, more preferably from 1 μm to 50 μm, and still more preferably from 5 μm to 40 μm. In a case in which the thickness of the photosensitive resin composition layer is 1 μm or more, industrial coating can be easily carried out. In a case in which the thickness is 100 μm or less, sufficient adhesiveness and resolution can be easily obtained.

The transmittance of ultraviolet rays through the photosensitive resin composition layer is preferably from 5% to 75%, more preferably from 10% to 65%, and still more preferably from 15% to 55%, with respect to ultraviolet rays with a wavelength of from 350 nm to 420 nm. In a case in which the transmittance is 5% or more, sufficient adhesiveness can be easily obtained. In a case in which the transmittance is 75% or less, sufficient resolution can be easily obtained. The transmittance can be measured by a UV spectrometer. The UV spectrometer used here may be a type 228A double beam spectrometer (manufactured by Hitachi, Ltd).

The photosensitive element may further include an intermediate layer such as a cushion layer, an adhesion layer, a light absorbing layer, or a gas barrier layer. For example, an intermediate layer described in JP-A No. 2006-098982 may be applied to the intermediate layer in the present invention.

The shape of the resulting photosensitive element is not particularly limited. The photosensitive element may be a sheet form, or may be wounded into a roll shape around a core. In a case in which the photosensitive element is wounded into a roll shape, it is preferable to wound the element such that the support film faces outside. Examples of the material for the core include plastics such as a polyethylene resin, a polypropylene resin, a polystyrene resin, a polyvinyl chloride resin, or an ABS resin (acrylonitrile-butadiene-styrene copolymer). On the edge of the photosensitive element roll thus obtained, it is preferable to provide an edge separator from the viewpoint of edge protection, and it is preferable to provide a moisture-proof edge separator from the viewpoint of edge fusion resistance. As the packing method, a black sheet with low moisture permeability is preferably used to pack.

The photosensitive element according to the present embodiment can be used, for example, in the method of forming a resist pattern described below.

Method of Forming Resist Pattern

The photosensitive resin composition can be used to form a resist pattern. The method of forming a resist pattern according to one embodiment of the present invention includes: (i) a process of forming, on a substrate, a photosensitive resin composition layer that is a coating film of the photosensitive resin composition (photosensitive layer forming process); (ii) a process of irradiating at least a part of an area of the photosensitive resin layer with active light rays (exposure process); and a process of removing an area, other than the area of the photosensitive resin composition layer irradiated with active light rays, from the substrate (developing process). The method of forming the resist pattern may further include other process if necessary.

(i) Photosensitive Layer Forming Process

First, the photosensitive resin composition layer, which is a coating film of the photosensitive resin composition, is formed on a substrate. The substrate used here may be a substrate (a substrate for forming circuits) provided with an insulating layer and a conductor layer formed on the insulating layer.

In a case in which the photosensitive element has the protective film 4, the photosensitive resin composition layer is formed on the substrate by removing the protective film and then contact bonding the photosensitive resin composition layer of the photosensitive element to the substrate while heating. As a result, the layered body in which the substrate, the photosensitive resin composition layer, and the support film are layered in this order can be obtained.

The photosensitive layer forming process is preferably carried out under reduced pressure from the viewpoint of adhesiveness and follow-up property. The temperature of applying heat to at least one of the photosensitive resin composition layer and the substrate during contact bonding is preferably from 70° C. to 130° C., and the contact bonding pressure thereof is preferably from about 0.1 MPa to about 1.0 MPa (about 1 kgf/cm² to about 10 kgf/cm²). These conditions are not particularly limited, and are appropriately selected as needed. In a case in which the photosensitive resin composition layer is heated at from 70° C. to 130° C., it is not necessary to subject the substrate to preheating in advance. However, preheating of the substrate for forming circuits can further improve adhesiveness and follow-up property.

(ii) Exposure Process

In the exposure process, at least a part of an area of the photosensitive resin layer thus formed on the substrate is irradiated with active light rays to cure the area irradiated with active light rays, thereby forming a latent image. In a case in which the support film on the photosensitive resin composition layer transmits active light rays, it is possible to irradiate active light lays through the support film. On the other hand, in a case in which the support film blocks active light lays, the support film is removed and then the photosensitive resin composition layer is irradiated with active light lays.

Examples of the exposure method include a method (mask exposure method) of irradiating active light rays imagewise through a negative or positive pattern, referred to as artwork. Alternatively, a method of irradiating active light rays imagewise by a direct writing exposure method such as LDI (Laser Direct Imaging) exposure method or DLP (Digital Light Processing) exposure method may be used.

The light source for the active light rays is not particularly limited, and may be a known light source. Examples of the light source include gas lasers such as a carbon arc lamp, a mercury vapor arc lamp, an ultra-high-pressure mercury lamp, a xenon lamp, or an argon laser; solid lasers such as a YAG laser; semiconductor lasers; ultraviolet rays such as a gallium nitride-based violet laser; and a lamp that efficiently emits visible light.

The wavelength of the active light rays (exposure wavelength) is preferably in a range of from 340 nm to 430 nm, and more preferably 350 nm to 420 nm, from the viewpoint of achieving the effect of the present invention more reliably.

(iii) Developing Process

In the developing process, an uncured area of the photosensitive resin composition layer is removed from the substrate for forming circuits through a development process, thereby forming a resist pattern, which is a cured material obtained by photo-curing the photosensitive resin composition layer, on the substrate. In a case in which the support film remains on the photosensitive resin composition layer, the support film is removed and then the unexposed area is removed (developed). Examples of the development process include wet development and dry development, and the wet development is widely used.

In the case of wet development, a developing solution suitable for the photosensitive resin composition is used and development is achieved by a known development method. Examples of the development method include a dip method, a paddle method, a spray method, brushing, slapping, scrapping, and dipping while shaking. From the viewpoint of improving resolution, a high-pressure spray method is suitable. The development may be carried out by combining two or more of these methods.

The developing solution is appropriately selected in accordance with the components of the photosensitive resin composition. Examples of the developing solution include an aqueous alkali solution, an aqueous developing solution, and an organic solvent developing solution.

The aqueous alkali solution used as the developing solution is safe and stable and has good handlebility. Examples of bases to be used for the aqueous alkali solution include alkali hydroxides such as a lithium, sodium or potassium hydroxide; alkali carbonates such as a lithium, sodium, potassium or ammonium carbonate or bicarbonate; alkali metal phosphates such as potassium phosphate or sodium phosphate; and alkali metal pyrophosphate such as sodium pyrophosphate or potassium pyrophosphate.

The aqueous alkali solution used as the developing solution is preferably a 0.1% by mass to 5% by mass sodium carbonate dilute solution, a 0.1% by mass to 5% by mass potassium carbonate dilute solution, a 0.1% by mass to 5% by mass sodium hydroxide dilute solution, or a 0.1% by mass to 5% by mass sodium tetraborate dilute solution. The pH of the aqueous alkali solution is preferably in a range of from 9 to 11. The temperature is adjusted in accordance with the alkali developing property of the photosensitive resin composition layer. The aqueous alkali solution may contain a surfactant, an antifoaming agent, a small amount of an organic solvent to accelerate development, or the like.

The aqueous developing solution is, for example, a developing solution including water or an aqueous alkali solution, and one or more organic solvents. Examples of based for the aqueous developing solution include, in addition to the bases described above, borax, sodium metasilicate, tetramethylammonium hydroxide, ethanolamine, ethylenediamine, diethyltriamine, 2-amino-2-hydrixymethyl-1,3-propanediol, 1,3-diamino-2-propanol, and morpholine. The pH of the aqueous developing solution is preferably as low as possible in a range allowing sufficient development, and is preferably from 8 to 12, and more preferably from 9 to 10.

Examples of the organic solvent used for the aqueous developing solution include acetone, ethyl acetate, an alkoxyethanols having alkoxy group of from 1 to 4 carbon atoms, ethyl alcohol, isopropyl alcohol, butyl alcohol, diethylene glycol monomethyl ether, diethylene glycol monoethyl ether, and diethylene glycol monobutyl ether. These solvents may be used singly, or in combination of two or more kinds thereof. In general, the content ratio of the organic solvent in the aqueous developing solution is preferably from 2% by mass to 90% by mass. The temperature of the organic solvent may be adjusted in accordance with the alkali developing property. The aqueous developing solution may contain a small amount of surfactant, antifoaming agent, or the like.

Examples of the organic solvent used for the organic solvent developing solution include 1,1,1-trichloroethane, N-methylpyrrolidone, N,N-dimethylformamide, cyclohexanone, methyl isobutyl ketone, and γ-butyrolactone. For anti-inflammability, it is preferable to add water to at least one of these organic solvents in a range of from 1% by mass to 20% by mass to prepare the organic solvent developing solution.

As needed, the method of forming a resist pattern may further include a process of heating at about 60° C. to 250° C. or exposing at about 0.2 J/cm² to 10 J/cm² after the removal of the unexposed area to further cure the resist pattern.

Method of Manufacturing Printed Wiring Board

The method of manufacturing a printed wiring board according to the present invention includes a process of etching or plating a substrate (substrate for forming circuits), which has an insulating layer and a conductor layer formed on the insulating layer and in which the resist pattern was formed on the conductor layer, by the method of forming a resist pattern to form a conductor pattern. As needed, the method of manufacturing a printed wiring board may include other process such as a resist removing process. The conductor layer or the like of the substrate is treated by etching or plating using the developed resist pattern as a mask.

In the etching treatment, using a resist pattern (cured resist) formed on the substrate as a mask, areas of the conductor layer of the substrate for forming circuits, the areas that is not covered with the cured resist, is removed by etching to form the conductor pattern. The method of etching is appropriately selected in accordance with components of the conductor layer to be removed. Examples of etching solutions include a cupric chloride solution, a ferric chloride solution, an alkali etching solution, and a hydrogen peroxide etching solution. Among these, it is preferable to use the ferric chloride solution in view of sufficient etch factor.

In the plating treatment, using a resist pattern (cured resist) formed on the substrate as a mask, cupper, a solder, and the like are plated on areas of the conductor layer of the substrate for forming circuits, the areas which is not covered with the cured resist. After plating, the cured resist is removed, and then the conductor layer that has been covered with the cured resist is subjected to etching, thereby forming the conductor pattern. The plating may be electrolytic plating, or non-electrolytic plating. Examples of the plating include copper plating such as copper sulfate plating or copper pyrophosphate plating; solder plating such as high throwing solder plating; nickel plating such as Walt bath (nickel sulfate-nickel chloride) plating or nickel sulfaminate plating; and gold plating such as hard gold plating or soft gold plating.

The resist pattern on the substrate is removed (released) after the etching and plating. For example, the removal of the resist pattern may be achieved by an aqueous solution of stronger alkalinity than the aqueous alkali solution used in the developing process. The strong alkaline aqueous solution used here may be a 1% by mass to 10% by mass sodium hydroxide aqueous solution or a 1% by mass to 10% by mass potassium hydroxide aqueous solution. Among these, it is preferable to use a 1% by mass to 10% by mass sodium or potassium hydroxide aqueous solution, and more preferable to use a 1% by mass to 5% by mass sodium or potassium hydroxide aqueous solution. Examples of the releasing method include a dipping method and a spraying method, and these methods are used singly or in combination of two or more kinds thereof.

In a case in which the resist pattern is removed after plating, the conductor layer that was covered with the cured resist can be further removed by etching to form the conductor pattern, whereby the intended printed wiring board can be manufactured. The etching method is appropriately selected in accordance with components of the conductor layer to be removed. For example, the above-described etching solution can be used.

The method of manufacturing the printed wiring board according to the present invention may be applied to manufacture of not only single-layer printed wiring boards but also multilayer printed wiring boards, and may be applied to manufacture of printed boards with miniature through-holes.

The photosensitive resin composition according to an embodiment of the present invention can be preferably used for manufacture of wiring boards. That is, an preferable embodiment of the present invention is an application of the photosensitive resin composition to manufacture printed wiring boards, in which the photosensitive resin composition includes component (A): a binder polymer that has a structural unit derived from (meth)acrylic acid, a structural unit derived from styrene, and a structural unit derived from benzyl (meth)acrylate; component (B): a photopolymerizable compound including a first bisphenol di(meth)acrylate that has an ethyleneoxy group and a propyleneoxy group, in which the number of the structural unit of the ethyleneoxy group is from 1 to 20 and the number of structural unit of the propyleneoxy group is from 2 to 7, and in which the total number of structural unit of the ethyleneoxy group and the propyleneoxy group is more than 10; and component (C): a photopolymerization initiator. More preferable embodiment of the present invention is an application of the photosensitive resin composition to manufacture a high density package substrate, and an application of the photosensitive resin composition to a semi-additive method. Hereinbelow, an example of a manufacturing method of a wiring board by a semi-additive process is explained with reference to the figure.

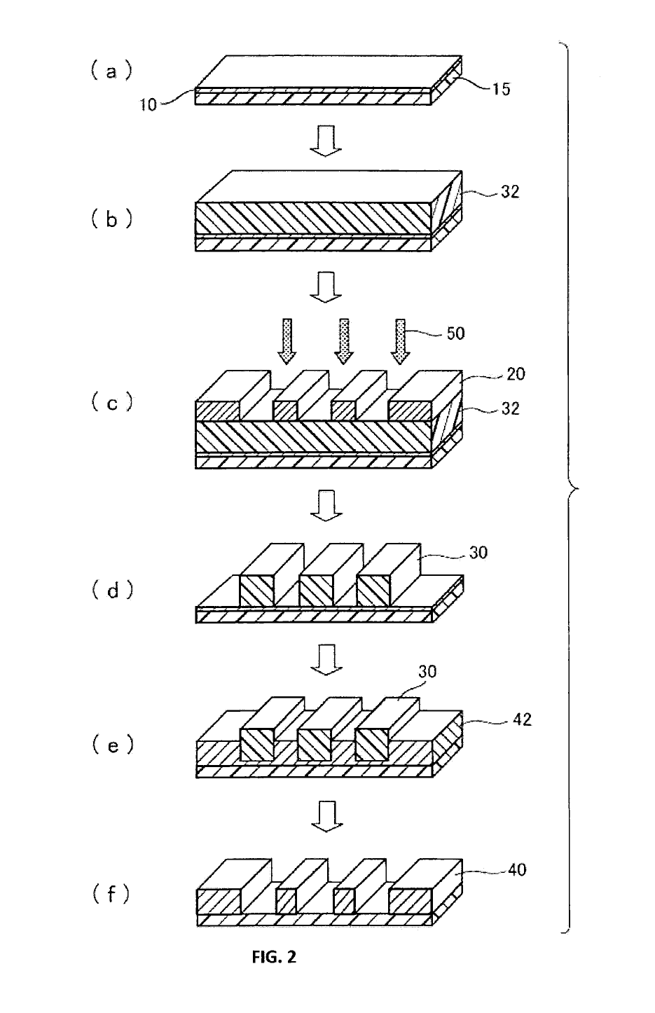

FIG. 2(a) shows preparation of a substrate (substrate for forming circuits) in which a conductor layer 10 is formed on an insulating layer 15. The conductor layer 10 is, for example, a metal copper layer. FIG. 2(b) shows formation of a photosensitive resin composition layer 32 on the conductor layer 10 of the substrate by the photosensitive layer forming process. FIG. 2(c) shows formation of a photo-cured area by arranging a mask 20 on the photosensitive resin composition layer 32 and exposing an area other than the area on which the mask 20 is arranged by irradiation of an active light ray 50. FIG. 2(d) shows formation of a resist pattern 30 as the photo-cured area on the substrate by removal of the area other than the photo-cured area formed by the exposure process from the substrate. FIG. 2(e) shows formation of a plated layer 42 on the conductor layer 10 by plate processing using as a mask the resist pattern 30 of the photo-cured area. FIG. 2(f) shows formation of a circuit pattern 40 by releasing the resist pattern 30 of the photo-cured area with a strong alkaline aqueous solution followed by etching to remove a part of the plated layer 42 and the conductor layer 10 that has been masked by the resist pattern 30. In FIGS. 2(a) to 2(f), the method of forming the resist pattern 30 using the mask 20 is described. However, the resist pattern 30 may be formed by a direct writing exposure method without the use of the mask 20.

### EXAMPLES

Hereinbelow, the present invention is described more specifically with reference to c Examples, but the present invention is not limited to these examples.

### Examples 1 to 7 and Comparative Examples 1 to 5

### Preparation of Solution of Photosensitive Resin Composition

Each of solutions of photosensitive resin compositions of Examples 1 to 7 and Comparative Examples 1 to 5 was prepared by mixing components (A) to (E) and a dye shown in Tables 2 and 3 in compounding amounts (unit: g) shown the tables with 9 g of acetone, 5 g of toluene, and 5 g of methanol. The compounding amount of the component (A) shown in Tables 2 and 3 is mass of non-volatile content (amount of solid content). The details of respective components shown in Tables 2 and 3 are as follows. Here, “-” in Tables 2 and 3 means that the component is not contained.

(A) Binder Polymer

Synthesis of Binder Polymer (A-1)

90 g of methacrylic acid, 6 g of methyl methacrylate, 150 g of styrene, and 54 g of benzyl methacrylate (mass ratio: 30/2/50/18) as polymerizable monomers (monomers) were mixed with 1.5 g of azobisisobutyronitrile, thereby obtaining a solution as “solution a”.

0.5 g of azobisisobutyronitrile was dissolved in 100 g of a mixture of 60 g methylcellosolve and 40 g toluene (mass ratio of 3:2), thereby obtaining a solution as “solution b”.

In a flask equipped with a stirrer, a reflux condenser, a thermometer, a dropping funnel, and a nitrogen gas inlet tube, 300 g of a mixture of 180 g methylcellosolve and 120 g toluene (mass ratio of 3:2) was added, and the resultant was stirred while blowing nitrogen gas into the flask and heated to 80° C.

The solution a was added dropwise to the mixture in the flask over a period of 4 hours, and then the resultant was kept for 2 hours at 80° C. while stirring. Subsequently, solution b was added dropwise to the mixture in the flask over a period of 10 minutes, and then the resultant was kept for 3 hours at 80° C. while stirring. The solution in the flask was then heated to 90° C. over a period of 30 minutes. The resultant was kept for 2 hours at 90° C. and then cooled, thereby obtaining a solution of a binder polymer (A-1).

With regard to the binder polymer (A-1), the non-volatile content (solid content) was 47.4% by mass, the weight-average molecular weight was 23,000, the acid value was 196 mgKOH/g, and the dispersivity was 2.7.

The weight-average molecular weight was measured by gel permeation chromatography (GPC) and calculation was performed using a standard polystyrene calibration curve. The GPC conditions were as follows.

GPC Conditions

Pump: Hitachi L-6000 (manufactured by Hitachi, Ltd.)

Column: the following three columns, column specifications: 10.7 mmφ×300 mm
Gelpack GL-R440;
Gelpack GL-R450; and
Gelpack GL-R400M (all manufactured by Hitachi Chemical Co., Ltd)

Eluent: tetrahydrofuran (THF)

Sample concentration: 150 mg of the binder polymer solution with a solid content of 47.4% by mass was measured off and dissolved in 5 mL of THF to prepare a sample

Measuring temperature: 40° C.

Charged amount: 200 μL

Pressure: 49 Kgf/cm² (4.8 MPa)

Flow rate: 2.05 mL/min

Detector: Hitachi L-3300 R1 (manufactured by Hitachi, Ltd.)

Synthesis of Binder Polymer (A-2)

90 g of methacrylic acid, 6 g of methyl methacrylate, 150 g of styrene, and 54 g of benzyl methacrylate (mass ratio: 30/2/50/18) as polymerizable monomers (monomers) were mixed with 0.72 g of azobisisobutyronitrile, thereby obtaining a solution as “solution a′”.

In a flask equipped with a stirrer, a reflux condenser, a thermometer, a dropping funnel, and a nitrogen gas inlet tube, 300 g of a mixture of 180 g methylcellosolve and 120 g toluene (mass ratio of 3:2) was added, and the resultant was stirred while blowing nitrogen gas into the flask and heated to 80° C.

The solution a′ was added dropwise to the mixture in the flask over a period of 4 hours, and then the resultant was kept for 2 hours at 80° C. while stirring. Subsequently, solution b was added dropwise to the mixture in the flask over a period of 10 minutes, and then the resultant was kept for 3 hours at 80° C. while stirring. The solution in the flask was then heated to 90° C. over a period of 30 minutes. The resultant was kept for 2 hours at 90° C. and then cooled, thereby obtaining a solution of a binder polymer (A-2).

Synthesis of Binder Polymers (A-3) and (A-4)

Each of solutions of binder polymer (A-3) and (A-4) was obtained in a manner similar to the method for obtaining the solution of the binder polymer (A-1), except that materials shown in Table 1 was used as the polymerizable monomers (monomers) in amounts shown in Table 1.

With regard to the binder polymers (A-1) to (A-4), the mass ratio (%) of the polymerizable monomers (monomers), the acid value, the weight-average molecular weight, and the dispersivity are shown in Table 1. Here, “-” in Table 1 means that the component is not contained.

TABLE 1

| | Methacrylic | Methyl | | Benzyl | Acid value | Weight-average | |
|---|---|---|---|---|---|---|---|
| | acid | methacrylate | Styrene | methacrylate | (mg/KOH) | molecular weight | Dispersivity |
| (A-1) | 30 | 2 | 50 | 18 | 196 | 23,000 | 2.7 |
| (A-2) | 30 | 2 | 50 | 18 | 196 | 44,000 | 1.6 |
| (A-3) | 20 | — | — | 80 | 131 | 25,000 | 2.7 |
| (A-4) | 30 | — | 50 | 20 | 196 | 24,000 | 2.7 |

(B) Photopolymerizable Compound
FA-321M: 2,2-bis(4-(methacryloxypentaethoxy)phenyl)propane (“FA-321M”, manufactured by Hitachi Chemical Co., Ltd)
FA-324M: 2,2-bis(4-(methacryloxydiethoxy)phenyl)propane (“FA-324M”, manufactured by Hitachi Chemical Co., Ltd)
FA-3200MY: 2,2-bis(4-(methacryloxyethoxypropoxy)phenyl)propane (an adduct of an average of 12 moles of ethyleneoxide and an average of 4 moles of propyleneoxide) (“FA-3200MY”, manufactured by Hitachi Chemical Co., Ltd)
BA-4PO10EO-DM: 2,2-bis(4-(methacryloxyethoxypropoxy)phenyl)propane (an adduct of an average of 10 moles of ethyleneoxide and an average of 4 moles of propyleneoxide) (“BA-4PO10EO-DM”, manufactured by Hitachi Chemical Co., Ltd)
BA-4PO8EO-DM: 2,2-bis(4-(methacryloxyethoxypropoxy)phenyl)propane (an adduct of an average of 8 moles of ethyleneoxide and an average of 4 moles of propyleneoxide) (“BA-4PO8EO-DM”, manufactured by Hitachi Chemical Co., Ltd)
BA-4PO6EO-DM: 2,2-bis(4-(methacryloxyethoxypropoxy)phenyl)propane (an adduct of an average of 6 moles of ethyleneoxide and an average of 4 moles of propyleneoxide) (“BA-4PO6EO-DM”, manufactured by Hitachi Chemical Co., Ltd)
BA-2PO8EO-DM: 2,2-bis(4-(methacryloxyethoxypropoxy)phenyl)propane (an adduct of an average of 8 moles of ethyleneoxide and an average of 2 moles of propyleneoxide) (“BA-2PO8EO-DM”, manufactured by Hitachi Chemical Co., Ltd.)

(C) Photopolymerization Initiator
B-CIM: 2,2′-bis(2-chlorophenyl)-4,4′,5,5′-tetraphenylbisimidazole (2-(2-chlorophenyl)-4,5-diphenylimidazole dimer; “B-CIM”, manufactured by Hampford Co.)

(D) Sensitizing Dye
PYR-1: 1-phenyl-3-(4-methoxystyryl)-5-(4-methoxyphenyl)pyrazoline (manufactured by Nippon Chemical Industrial Co., Ltd.)

(E) Amine Compound
LCV: Leuco crystal violet (“LCV”, manufactured by Yamada Chemical Co., Ltd.)

Dye
MKG: Malachite Green (“MKG”, manufactured by Osaka Organic Chemistry, Ltd.)

TABLE 2

| | | Example | | | | | | |
|---|---|---|---|---|---|---|---|---|
| Component | | 1 | 2 | 3 | 4 | 5 | 6 | 7 |
| (A) | (A-1) | 48 | 48 | 49 | 49 | 49 | — | — |
| | (A-2) | — | — | — | — | — | 50 | — |
| | (A-3) | — | — | — | — | — | — | — |
| | (A-4) | — | — | — | — | — | — | 50 |
| (B) | FA-321M | — | 12 | — | — | — | — | — |
| | FA-324M | 30 | 30 | 30 | 30 | 30 | 30 | 30 |
| | FA-3200MY | 22 | 10 | 21 | — | — | 20 | 22 |
| | BA-4PO10EO-DM | — | — | — | 21 | — | — | — |
| | BA-4PO8EO-DM | — | — | — | — | 21 | — | — |
| | BA-4PO6EO-DM | — | — | — | — | — | — | — |
| | BA-2PO8EO-DM | — | — | — | — | — | — | — |
| (C) | B-CIM | 4 | 4 | 4 | 4 | 4 | 4 | 4 |
| (D) | PYR-1 | 0.10 | 0.10 | 0.10 | 0.10 | 0.10 | 0.18 | 0.18 |
| (E) | LCV | 0.65 | 0.65 | 0.65 | 0.65 | 0.65 | 0.65 | 0.65 |
| Dye | MKG | 0.03 | 0.03 | 0.03 | 0.03 | 0.03 | 0.03 | 0.03 |

TABLE 3

| | | Comparative Example | | | | |
|---|---|---|---|---|---|---|
| Component | | 1 | 2 | 3 | 4 | 5 |
| (A) | (A-1) | 50 | — | — | — | — |
| | (A-2) | — | 50 | 50 | 50 | — |
| | (A-3) | — | — | — | — | 48 |
| | (A-4) | — | — | — | — | — |
| (B) | FA-321M | 20 | 20 | — | — | 25 |
| | FA-324M | 30 | 30 | 30 | 30 | 10 |
| | FA-3200MY | — | — | — | — | 5 |
| | BA-4PO10EO-DM | — | — | — | — | — |
| | BA-4PO8EO-DM | — | — | — | — | — |
| | BA-4PO6EO-DM | — | — | 20 | — | — |
| | BA-2PO8EO-DM | — | — | — | 20 | — |
| (C) | B-CIM | 4 | 4 | 4 | 4 | 4 |
| (D) | PYR-1 | 0.10 | 0.18 | 0.10 | 0.18 | 0.18 |
| (E) | LCV | 0.65 | 0.65 | 0.65 | 0.65 | 0.65 |
| Dye | MKG | 0.03 | 0.03 | 0.03 | 0.03 | 0.03 |

Manufacture of Photosensitive Element

Each of the solutions of photosensitive resin composition obtained above was coated onto a polyethylene terephthalate film with a thickness of 16 μm (“FB-40”, manufactured by Toray Industries, Inc.) and subsequently dried at 70° C. and 110° C. with a hot air current drier, thereby forming a photosensitive resin composition layer with a post-drying thickness of 25 μm. A protective film (“E-200K”, manufactured by Oji Paper Co., Ltd.) was attached onto the photosensitive resin composition layer, thereby obtaining a photosensitive element including the polyethylene terephthalate film (support film), the photosensitive resin composition layer, and the protective film layered in this order.

Manufacture of Multilayer Substrate

The copper-clad laminate (“MCL-E-679F”, manufactured by Hitachi Chemical Co., Ltd.) including a glass epoxy material and a copper foil (thickness: 16 μm) formed on both sides thereof (hereinafter, also referred to as “substrate”) was heated to raise the temperature to 80° C. Subsequently, using each of the photosensitive elements of Examples 1 to 7 and Comparative Examples 1 to 5, the photosensitive layer was layered (laminated) on the copper surface of the substrate. The lamination was accomplished under conditions with a temperature of 120° C. and a lamination pressure of 4 kgf/cm² (0.4 MPa) while removing the protective film, such that the photosensitive resin composition layer of each photosensitive element was closely bonded to the copper surface of the substrate. Thus, a multilayer substrate including the photosensitive resin composition layer and the polyethylene terephthalate film layered on the copper surface of the substrate was obtained.

The obtained multilayer substrate was allowed to cool to 23° C. Subsequently, a phototool having a 41-step tablet with a density region of from 0.00 to 2.00, a density step of 0.05, a tablet size of 20 mm×187 mm, and a size of each step of 3 mm×12 mm, was arranged on the polyethylene terephthalate film of the multilayer substrate. A direct writing exposure machine (“DE-1UH”, manufactured by Hitachi Via Mechanicals, Ltd.) employing a violet laser diode with a wavelength of 405 nm as the light source was used for exposure of the photosensitive resin composition layer through the phototool and the polyethylene terephthalate film, at an energy dose (exposure dose) of 100 mJ/cm². The measurement of illuminance was performed using an ultraviolet illuminometer employing a 405 nm-responding probe (“UIT-150”, manufactured by Ushio Inc.).

Evaluation of Sensitivity

Following exposure, the polyethylene terephthalate film was released from the multilayer substrate to lay bare the photosensitive resin composition layer, and 1% by mass aqueous sodium carbonate at 30° C. was sprayed for 60 seconds thereto, thereby removing unexposed areas. Thus a resist pattern including a cured photosensitive resin composition on the copper surface of the substrate was formed. A number of remaining steps of the step tablet (step number) obtained as the resist pattern (cured film) was then counted to evaluate the sensitivity of the photosensitive resin composition. The sensitivity is represented as the step number, with a greater number of steps indicating more satisfactory sensitivity. The results are shown in Tables 4 and 5.

Evaluation of Resolution and Adhesiveness

A drawing with a line width (L)/space width (S) (hereinafter, referred to as “L/S”) of from 3/3 to 30/30 (units: μm) was used for exposure (drawing) of the photosensitive resin composition layer on the multilayer substrate at an energy dose for 16 steps remaining on the 41-step tablet. Following exposure, developing treatment was carried out in the same manner as for evaluation of sensitivity described above.

After development, the resolution and adhesiveness were evaluated by the minimum value among the line width/space width values for resist patterns with cleanly removed space areas (unexposed areas), and without meandering or defecting of the line areas (exposed areas). A smaller numerical value indicates more satisfactory resolution and adhesiveness. The results are shown in Tables 4 and 5.

Evaluation of Flexibility

The flexibility of the resist pattern was evaluated as follows. An FPC (Flexible Printed Circuit) substrate (“F-30VC1”, manufactured by Nikkan Industries Co., Ltd., substrate thickness: 25 μm, copper thickness: 18 μm) was heated to 80° C., and the photosensitive resin composition layer and the support film of each of the photosensitive elements according to Examples 1 to 7 and Comparative Examples 1 to 5 were layered on the copper surface of the substrate using a heat roll at a temperature of 110° C. and at a speed of 1.5 m/min while releasing the protective film, such that the photosensitive resin composition layer faced the FPC substrate side. The FPC substrate on which the photosensitive resin composition layer and the support were layered was used as a test piece for evaluating flexibility. A direct writing exposure machine (“DE-1UH”, manufactured by Hitachi Via Mechanicals, Ltd.) employing a violet laser diode with a wavelength of 405 nm as the light source was used for exposure of the test piece at an energy dose for 16 steps remaining on the 41-step tablet, thereby photo-curing the photosensitive resin composition layer. Subsequently, the support film was released and the resultant was developed, thereby obtaining a substrate for evaluating flexibility in which a resist pattern layered on the FPC substrate.

The flexibility was evaluated based on the mandrel test. The substrate for evaluating flexibility was cut into a strip with a width of 2 cm and a length of 10 cm, and then 1 rubbed against a cylindrical bar back and forth 5 times at an angle of 180°. Subsequently, the minimum value among the diameter (mm) of the cylinder without peeling between the FPC substrate and the resist pattern was determined. A smaller diameter of the cylinder indicates more satisfactory flexibility. The results are shown in Tables 4 and 5.

Evaluation of Developability

The minimum developing time (second) was measured as follows to evaluate the developability of the photosensitive resin composition layer.

The multilayer substrate was cut into 5 cm square to form a multilayer substrate for evaluation. The minimum developing time (second) required for developing the resulting unexposed multilayer substrate for evaluation until no photosensitive resin composition layer was left on the substrate was measured.

TABLE 4

| | Example | | | | | | |
|---|---|---|---|---|---|---|---|
| Item | 1 | 2 | 3 | 4 | 5 | 6 | 7 |
| Sensitivity | 16 | 16 | 16 | 16 | 16 | 16 | 16 |
| (step number/41) | | | | | | | |
| Resolution/Adhesiveness | 10 | 10 | 12 | 12 | 11 | 8.5 | 10 |
| (μm) | | | | | | | |
| Flexibility (φ, mm) | 6 | 8 | 8 | 8 | 10 | 12 | 8 |
| Minimum developing time | 17 | 20 | 19 | 21 | 27 | 20 | 18 |
| (second) | | | | | | | |

TABLE 5

| | Comparative Example | | | | |
|---|---|---|---|---|---|
| Item | 1 | 2 | 3 | 4 | 5 |
| Sensitivity | 16 | 16 | 15 | 15 | 16 |
| (step number/41) | | | | | |
| Resolution/Adhesiveness | 8 | 8 | 8 | 8 | 14 |
| (μm) | | | | | |
| Flexibility (φ, mm) | 20 | 20 | >25 | 25 | 12 |
| Minimum developing time | 24 | 22 | 34 | 29 | 18 |
| (second) | | | | | |

As clearly shown in Tables 4 and 5, the resist pattern formed using the photosensitive resin composition that includes a specific binder polymer and the bisphenol di(meth)acrylate having an ethyleneoxy group having from 1 to 20 structural units and a propyleneoxy group having from 2 to 7 structural units, with the total number of the structural unit being more than 10, was satisfactory in terms of all of the properties of resolution, adhesiveness, and flexibility. Furthermore, the photosensitive resin composition was satisfactory in terms of developability.

The embodiment of the present invention is described below.

<1> A photosensitive resin composition comprising:

a binder polymer that has a structural unit derived from (meth)acrylic acid, a structural unit derived from styrene or α-methyl styrene, and a structural unit derived from benzyl (meth)acrylate;

a photopolymerizable compound comprising a first bisphenol di(meth)acrylate that has an ethyleneoxy group and a propyleneoxy group, wherein a number of structural units of the ethyleneoxy group is from 1 to 20 and a number of structural units of the propyleneoxy group is from 2 to 7, and wherein a total number of structural units of the ethyleneoxy group and the propyleneoxy group is more than 10; and

a photopolymerization initiator.

<2> The photosensitive resin composition according to <1>, further comprising at least one sensitizing dye selected from the group consisting of a pyrazoline derivative and a bis-alkoxy anthracene.
<3> The photosensitive resin composition according to <1> or <2>, further comprising a second bisphenol di(meth)acrylate, which is different from the first bisphenol di(meth)acrylate, and which has an ethyleneoxy group, wherein a number of structural units of the ethyleneoxy group is 8 or less.
<4> A photosensitive element including:

a support film; and

a photosensitive resin composition layer that is provided on the support film and that is a coating film of the photosensitive resin composition according to any one of <1> to <3>.

<5> A method of forming a resist pattern, the method including:

a photosensitive layer forming process of forming, on a substrate, a photosensitive resin composition layer that is a coating film of the photosensitive resin composition according to any one of claims 1 to 3;

a process of irradiating at least a part of an area of the photosensitive resin composition layer with active light rays; and

a process of removing an area, other than the area of the photosensitive resin composition layer irradiated with active light rays, from the substrate.

<6> The method of forming a resist pattern according to <5>, wherein the active light rays have a wavelength in a range of from 340 nm to 430 nm.
<7> A method of manufacturing a printed wiring board including a process of etching or plating the substrate on which the resist pattern was formed by the method of forming a resist pattern according to <5> or <6>.

The disclosure of Japanese Patent Application No. 2012-254405 filed on Nov. 20, 2012 is incorporated herein by reference in its entirety.

All publications, patent applications, and technical standards mentioned in the present specification are herein incorporated by reference to the same extent as if each individual publication, patent application, or technical standard was specifically and individually indicated to be incorporated by reference.

1. A photosensitive resin composition comprising:
a binder polymer that has a structural unit derived from (meth)acrylic acid, a structural unit derived from styrene or α-methyl styrene, and a structural unit derived from benzyl (meth)acrylate;
a photopolymerizable compound comprising a first bisphenol di(meth)acrylate that has an ethyleneoxy group and a propyleneoxy group, wherein a number of structural units of the ethyleneoxy group is from 1 to 20 and a number of structural units of the propyleneoxy group is from 2 to 7, and wherein a total number of structural units of the ethyleneoxy group and the propyleneoxy group is more than 10; and
a photopolymerization initiator.

2. The photosensitive resin composition according to claim 1, further comprising at least one sensitizing dye selected from the group consisting of a pyrazoline derivative and a bis-alkoxy anthracene.

3. The photosensitive resin composition according to claim 1, further comprising, a second bisphenol di(meth)acrylate, which is different from the first bisphenol di(meth)acrylate, and which has an ethyleneoxy group, wherein a number of structural units of the ethyleneoxy group is 8 or less.

4. A photosensitive element comprising:
a support film; and
a photosensitive resin composition layer that is provided on the support film and that is a coating film of the photosensitive resin composition according to claim 1.

5. A method of forming a resist pattern, the method comprising:
a photosensitive layer forming process of forming, on a substrate, a photosensitive resin composition layer that is a coating film of the photosensitive resin composition according to claim 1;
a process of irradiating at least a part of an area of the photosensitive resin composition layer with active light rays; and
a process of removing an area other than the area of the photosensitive resin composition layer irradiated with active light rays from the substrate.

6. The method of forming a resist pattern according to claim 5, wherein the active light rays have a wavelength in a range of from 340 nm to 430 nm.

7. A method of manufacturing a printed wiring board comprising a process of etching or plating the substrate on which the resist pattern was formed by the method of forming a resist pattern according to claim 5.
